(19) United States
(12) Patent Application Publication
(10) Pub. No.: US 2018/0114550 A1
(43) Pub. Date: Apr. 26, 2018

(54) MEMORY SYSTEM INCLUDING MEMORY DEVICE AND MEMORY CONTROLLER

(71) Applicant: SK hynix Inc., Gyeonggi-do (KR)

(72) Inventor: Yong-Deok CHO, Gyeonggi-do (KR)

(21) Appl. No.: 15/622,157

(22) Filed: Jun. 14, 2017

(30) Foreign Application Priority Data
Oct. 21, 2016 (KR) 10-2016-0137338

(51) Int. Cl. G11C 7/04; G11C 7/22

(52) U.S. Cl. CPC G11C 7/04; G11C 2207/229; G11C 7/22

(57) ABSTRACT

A memory system includes a memory device configured to store input data with a first time interval that is adjusted in response to a write command and a precharge command; and a controller configured to generate the write command and the precharge command, and to control the memory device, wherein the controller sets a change rate of the first time interval according to a temperature of the memory device, and adjusts a time interval between the write command and the precharge command on a basis of the set change rate and the temperature of the memory device.

### CROSS-REFERENCE TO RELATED APPLICATIONS

The present application claims priority of Korean Patent Application No. 10-2016-0137338, filed on Oct. 21, 2016, which is incorporated herein by reference in its entirety.

### BACKGROUND

### 1. Field

Exemplary embodiments relate to a memory system, and more particularly, to a memory system including a memory controller for adjusting operation timings of a memory device according to a temperature.

### 2. Description of the Related Art

A memory system is applied to various electronic devices for consumers or industry, for example, computers, cellular phones, personal digital assistants (PDAs), digital cameras, game machines, navigation devices and the like, and can be used as a main storage device or an auxiliary storage device. A memory device for implementing the memory system is largely classified into a volatile memory device and a nonvolatile memory device.

The volatile memory device has a fast write and read speed, but stored data is lost when power is off. The volatile memory device includes a dynamic random access memory (DRAM), a static RAM (SRAM) and the like. Alternatively, the nonvolatile memory device has a relatively slow write and read speed, but stored data is retained even when power is off. Accordingly, to store data to be substantially maintained regardless of the supply of power, the nonvolatile memory device is used. The nonvolatile memory device includes a read only memory (ROM), a mask ROM (MROM), a programmable ROM (PROM), an erasable programmable ROM (EPROM), an electrically erasable programmable ROM (EEPROM), a flash memory, a phase change random access memory (PCRAM), a magnetic RAM (MRAM), a resistive RAM (RRAM), a ferroelectric RAM (FRAM) and the like.

In order to substantially prevent an operation error and the like of a memory system, manufactures and venders of the memory device stipulate specifications for a stable operation of the memory device. These specifications are based on the worst case scenario which may occur in the memory device, but there may be a difference between the specifications and the actual performance and conditions of the memory device.

For example, in the DRAM, there exists a physical time required when one memory cell normally stores data. That is, to write data in a memory cell and then read the written data from the memory cell without errors, a prescribed time is required. This is a write recovery time (tWR) and characteristics related to this may be stipulated in the DRAM as specifications. For example, the write recovery time (tWR) of the DRAM may stipulated from the input time of a write command to the input time of a precharge command corresponding thereto. When the write recovery time (tWR) characteristic is set with a sufficient margin, it may deteriorate a high speed operation of the memory device, but when the write recovery time (tWR) characteristic is set without margin, a write operation may not be normally completed and a read error may occur.

In addition, as the process technology of the memory device is developed and its size is gradually reduced, resistance of a bit line or a storage node may increase, resulting in a change in time required for storing data. Particularly, since such a parameter is sensitive to the operation temperature of the memory device, it is necessary to improve the performance of the memory system through control optimized to a temperature, as well as specification-based control.

### SUMMARY

Various embodiments are directed to a memory controller capable of optimizing the performance of a memory device by measuring the temperature of the memory device and adjusting the operation timings of the memory device on the basis of the measured temperature, and a memory system including the same.

In accordance with an embodiment of the present invention, a memory system includes: a memory device configured to store input data with a first time interval that is adjusted in response to a write command and a precharge command; and a controller configured to generate the write command and the precharge command, and to control the memory device, wherein the controller sets a change rate of the first time interval according to a temperature of the memory device, and adjusts a time interval between the write command and the precharge command on a basis of the set change rate and the temperature of the memory device.

In accordance with an embodiment of the present invention, a memory system includes: a memory device configured to generate and output a digital code based on an internal temperature; and a controller configured to generate write and precharge commands for a write operation of the memory device, and to control the memory device, wherein the controller decreases a time interval between the write command and the precharge command on a basis of the digital code as the internal temperature of the memory device increases.

### BRIEF DESCRIPTION OF THE DRAWINGS

FIG. 1 is a block diagram illustrating a memory system in accordance with an embodiment of the present invention.

FIG. 2 is a diagram describing a configuration of a temperature code provided to a controller from a memory device illustrated in FIG. 1.

FIG. 3 is a block diagram illustrating a timing scheduler illustrated in FIG. 1.

FIG. 4 is a diagram illustrating a command generation timing by a controller illustrated in FIG. 1.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

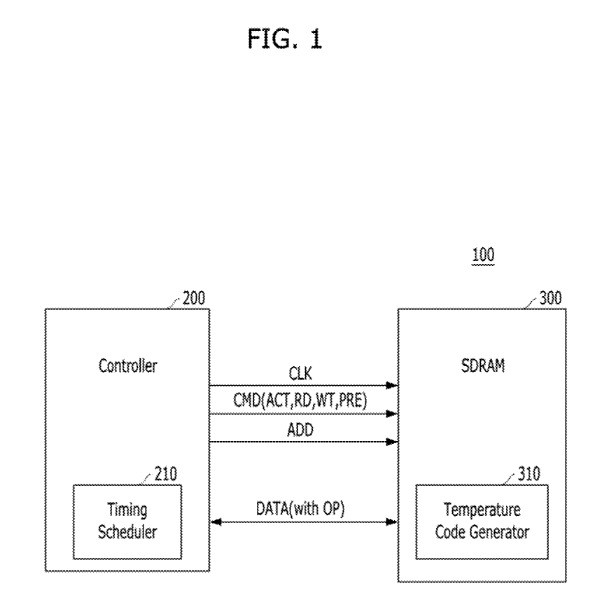

FIG. 1 is a block diagram illustrating a memory system 100 in accordance with an embodiment of the present invention.

Referring to FIG. 1, the memory system 100 may include a controller 200 and a memory device 300.

The memory system 100 operates in response to a request from a host (not illustrated), and particularly may store data DATA that is accessed by the host. The memory system 100 may be used as a main storage device or an auxiliary storage device of the host. In response to the request from the host, the controller 200 may generate a command CMD and an address ADD to control the memory device 300.

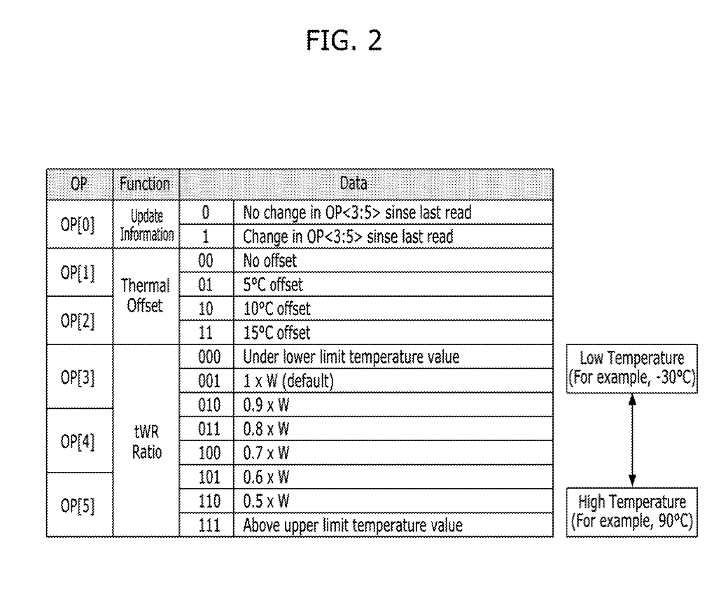

The memory device 300 may include a synchronous DRAM (SDRAM). The memory device 300 may store the data DATA in synchronization with a clock CLK that is provided from the controller 200, and provide the stored data DATA. The memory device 300 in accordance with the embodiment may include a temperature code generator 310. The temperature code generator 310 may monitor the internal temperature of the memory device 300, and provide the controller 200 with the monitored internal temperature as a digital temperature code OP together with the data DATA. A configuration of the temperature code OP generated by the temperature code generator 310 will be described in more detail with reference to FIG. 2.

The controller 200 provides an active command ACT to perform a row selection operation of the memory device 300. After a period corresponding to a row access strobe (RAS) to a column access strobe (CAS) delay time tRCD from the time point at which the active command ACT has been provided, the controller 200 provides read and write commands RD/WT to perform read and write operations of the memory device 300. This is due to a time being required until a data of a memory cell electrically coupled to a row that is, a word line selected by the row selection operation is sensed and amplified by a sense amplifier (not illustrated) in the memory device 300.

Particularly, in accordance with the embodiment, the controller 200 may provide a precharge command PRE, which disables a word line selected in the memory device 300 according to the write command WT and precharges columns corresponding thereto, in consideration of a write recovery time (tWR) from the time point at which the write command WT has been provided. The controller 200 may include a timing scheduler 210 for setting a change rate of the write recovery time (tWR) according to the temperature of the memory device 300, and adjusting a time interval between the write command WT and the precharge command PRE on the basis of the set change rate and the temperature code OP inputted from the temperature code generator 310.

As described above, the write recovery time (tWR) may correspond to a physical time required for a memory cell (not illustrated) included in the memory device 300 to normally store data. Such a physical time may sensitively respond to an operation temperature of the memory device 300, and particularly, the memory cell may require a longer physical time to store normal data at a low temperature as compared with a high temperature.

For example, in a DRAM mobile product, when its operation temperature is 90° C., the write recovery time (tWR) characteristic indicates approximately 3 ns to 4 ns, but when the operation temperature is −30° C., the write recovery time (tWR) may deteriorate to approximately 12 ns to 15 ns. Therefore, when the write recovery time (tWR) characteristic of the memory device 300 is set to a low temperature, performance deterioration at a high temperature is inevitable, and when the write recovery time (tWR) characteristic of the memory device 300 is set to a high temperature, a write/read operation error at a low temperature is unavoidable.

In this regard, the memory system 100 in accordance with the embodiment may measure the operation temperature of the memory device 300 and may flexibly control the write recovery time (tWR) characteristic on the basis of the measured temperature. That is, the timing scheduler 210 of the controller 200 may adjust a time interval between the write command WT and the precharge command PRE corresponding to the write recovery time (tWR) characteristic on the basis of the operation temperature of the memory device 300. The memory device 300 may store data with a first time interval that is adjusted in response to the write command WT and the precharge command PRE provided from the controller 200.

To measure the operation temperature of the memory device 300, FIG. 1 illustrates that the memory device 300 includes the temperature code generator 310 that monitors an internal temperature. However, the embodiment is not limited thereto. The memory system 100 or the controller 200 may include a temperature sensor (not illustrated) for measuring the operation temperature of the memory device 300.

Hereinafter, with reference to FIG. 2, an operation for measuring the operation temperature of the memory device in accordance with the embodiment will be described in more detail.

FIG. 2 is a diagram for describing a configuration of the temperature code OP provided to the controller 200 from the memory device 300 illustrated in FIG. 1. The temperature code generator 310 included in the memory device 300 may monitor an internal temperature, generate and provide the monitored internal temperature as the temperature code OP which is a digital code to the controller 200. FIG. 2 illustrates that the temperature code OP is composed of a 6-bit data structure; however, the embodiment is not limited thereto.

Referring to FIG. 2, the temperature code OP provided to the controller 200 from the memory device 300 may include a first code OP[3:5] indicating the monitored internal temperature of the memory device 300, and a second code OP[0:2] indicating an offset and update information of the first code OP[3:5]. The first code OP[3:5] may be set on the basis of a rate at which the write recovery time (tWR) characteristic of the memory device 300 changes depending on temperature.

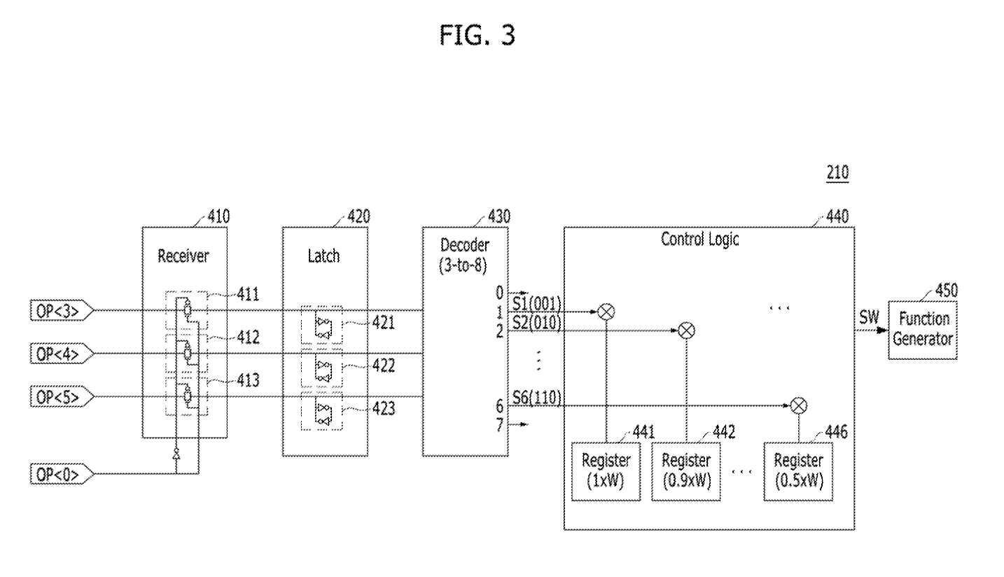

For example, the first code OP[3:5] Illustrated in FIG. 2 includes 3-bit data indicating 8 temperature values corresponding to respective data 000, 001, 010, 011, 100, 101, 110, and 111. When the change rate of the write recovery time (tWR) characteristic changes depending on a temperature period, the data of the first code OP[3:5] may be finely set in a temperature period in which the change rate is large, and the data of the first code OP[3:5] may be widely set in a temperature period in which the change rate is small. Since the write recovery time (tWR) characteristic changes at a faster rate in a low temperature period than in a high temperature period, the data 000 and 001 of the first code OP[3:5] may be set to finer values of temperature than the data 110 and 111 of the first code OP[3:5]. However, the embodiment is not limited thereto, and the data of the first code OP[3:5] may be set at a prescribed regular rate according to the temperature periods, thereby respectively indicating substantially the same temperature period. In this case, on the basis of the change rate of the write recovery time (tWR) characteristic according to the temperature periods, change rates of weights W respectively corresponding to the data of the first code OP[3:5] may be differently set. This will be described in more detail with reference to FIG. 3.

When the monitored internal temperature is greater than or equal to an upper limit temperature value for example, 90° C., the temperature code generator 310 may generate the first code OP[3:5] having data 111. When the monitored internal temperature is lower than a lower limit temperature value for example, −30° C., the temperature code generator 310 may generate the first code OP[3:5] having data 000. When the monitored internal temperature is between the upper limit temperature value and the lower limit temperature value, that is, within an operation permission range such as, −30° C.≤temperature<90° C., the temperature code generator 310 may generate the first code OP[3:5] as corresponding data from 001 to 110. At this time, on the basis of the provided data from 001 to 110 of the first code OP[3:5], the controller 200 may apply different weights 1*W, 0.9*W, 0.8*W, 0.7*W, 0.6*W, and 0.5*W to the time interval of the write command WT and the precharge command PRE.

The second code OP[0:2] may indicate the offset and update information of the first code OP[3:5] indicating the monitored internal temperature. A first bit OP[0] of the second code OP[0:2] is a flag signal which transits to a high level or a low level according to whether the first code OP[3:5] has been updated. As illustrated in FIG. 2, second and third bits OP[1:2] of the second code OP[0:2] may divide the offset for the monitored internal temperature into four steps at an interval of 5° C. from ‘no offset’. This compensates for a deviation of the monitored internal temperature. The deviation of the monitored internal temperature may change depending on an error of a temperature sensor (not illustrated) of the temperature code generator 310 and system environments. Depending on additional information required for the first code OP[3:5], the temperature code OP illustrated in FIG. 2 may include a larger or smaller amount of bit data.

FIG. 3 is a block diagram illustrating the timing scheduler 210 illustrated in FIG. 1.

Referring to FIG. 3, the timing scheduler 210 may include a receiver 410, a latch 420, a decoder 430, and a control logic 440.

The receiver 410 may receive the temperature code OP from the memory device 300. Particularly, in response to the first bit OP[0] of the second code OP[0:2] indicating whether the first code OP[3:5] has been updated, the receiver 410 may transmit the first code OP[3:5] to the latch 420. The receiver 410 may include first to third transmission gates 411 to 413 corresponding to respective bits of the first code OP[3:5]. The respective transmission gates 411 to 413 may transmit corresponding bits of the first code OP[3:5] to the latch 420 in response to the first bit OP[0] of the second code OP[0:2]. For example, when the first bit OP[0] of the second code OP[0:2]transits to a high level, the transmission gates 411 to 413 may be turned on to transmit the first code OP[3:5], and when the first bit OP[0] of the second code OP[0:2] transits to a low level, the transmission gates 411 to 413 may be turned off to block the transmission of the first code OP[3:5].

The latch 420 may store the first code OP[3:5] transmitted from the receiver 410 and transfer the first code OP[3:5] to the decoder 430. When the first bit OP[0] of the second code OP[0:2]transits to a high level and the updated first code OP[3:5] are inputted, the latch 420 stores the inputted first code OP[3:5] and transfers the first code OP[3:5] to the decoder 430. When the first bit OP[0] of the second code OP[0:2] transits to a low level, the latch 420 substantially maintains a previously stored value. The latch 420 may include first to third latch circuits 421 to 423 corresponding to the respective bits of the first code OP[3:5].

The decoder 430 may decode the first code OP[3:5] and output a plurality of selection signals. As illustrated in FIG. 3, the decoder 430 may decode a 3-bit signal to output an 8-bit signal. However, as illustrated in FIG. 2, the data 111 of the first code OP[3:5] indicates that the temperature of the memory device 300 is greater than or equal to the upper limit temperature value for example, 90° C., and the data 000 of first code OP[3:5] indicates that the temperature is lower than the lower limit temperature value for example, −30° C. Accordingly, the selection signals may not be activated according to the data 000 and 111 of the first code OP[3:5], and the decoder 430 may output first to sixth selection signals S1 to S6 to the control logic 440, each corresponding to the remaining data 001 to 110 of the first code OP[3:5].

The control logic 440 may include first to sixth registers 441 to 446 corresponding to the first to sixth selection signals S1 to S6 received from the decoder 430, respectively. The first to sixth registers 441 to 446 may respectively store the weights 1*W, 0.9*W, 0.8*W, 0.7*W, 0.6*W, and 0.5*W which are different from one another. As described above, the weights 1*W, 0.9*W, 0.8*W, 0.7*W, 0.6*W, and 0.5*W stored in the first to sixth registers 441 to 446 may be set on the basis of the rate at which the write recovery time (tWR) characteristic of the memory device 300 changes depending on temperature. That is, when the change rate of the write recovery time (tWR) characteristic changes depending on a temperature period, the change rate of the weight W may be increased in a temperature period in which the change rate is large, and the change rate of the weight W may be decreased in a temperature period in which the change rate is small.

As a consequence, the control logic 440 may select the weights 1*W, 0.9*W, 0.8*W, 0.7*W, 0.6*W, and 0.5*W stored in the corresponding registers 441 to 446 in response to the first to sixth selection signals S1 to S6, and output a selected weight SW. That is, since the first to sixth selection signals S1 to S6 are activated on the basis of the temperature code OP indicating the monitored temperature of the memory device 300, the control logic 440 may select and output different weights according to the monitored temperature.

The weight selected by the control logic 440 may be applied to a logic by which the controller 200 generates commands. Particularly, in accordance with the embodiment, the selected weight SW may be applied to a logic for generating the write command WT and the precharge command PRE. The selected weight SW may indicate a delay time. For example, the timing scheduler 210 may further include a function generator 450 for generating commands, wherein the function generator 450 may adjust a time interval between the write command WT and the precharge command PRE on the basis of a delay time according to an applied weight, thereby generating respective commands.

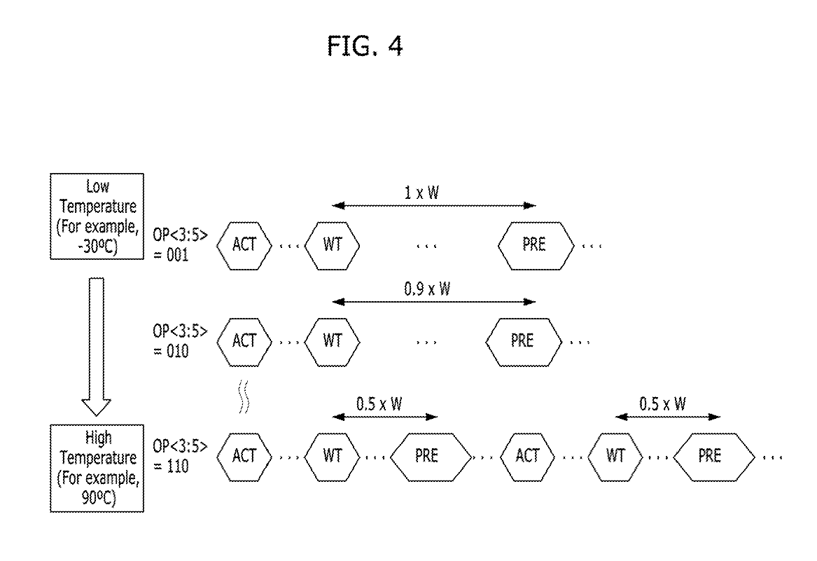

FIG. 4 is a diagram illustrating a command generation timing by the controller 200 illustrated in FIG. 1.

As described above, the controller 200 may provide the active command ACT for performing the row selection operation of the memory device 300. Then, the controller 200 provides write data together with the write command WT and controls the memory device 300 to store the write data in a selected memory cell. In accordance with the embodiment, the controller 200 may provide the precharge command PRE by adjusting a timing from the time point at which the write command WT has been provided.

For example, referring to a first timing diagram of FIG. 4, when the temperature code OP generated from the temperature code generator 310 of the memory device 300, that is, the first code OP[3:5], indicates the data 001, the timing scheduler 210 of the controller 200 may select the weight 1*W on the basis of the data 001. Accordingly, the function generator 450 may generate the precharge command PRE after a delay time corresponding to the weight 1*W passes from generating of the write command WT. That is, the data 001 of the first code OP[3:5] indicates that the memory device 300 operates at a relatively lower temperature of an operation permission range for example, −30° C.≤temperature<90° C. Consequently, the write recovery time (tWR) characteristic of the memory device 300 may have the largest value, and the controller 200 may generate the write command WT and the precharge command PRE at the delay time corresponding to the weight 1*W having the largest value.

Referring to a second timing diagram of FIG. 4, when the first code OP[3:5] indicates the data 010, the timing scheduler 210 of the controller 200 may select the weight 0.9*W on the basis of the data 010. Accordingly, the function generator 450 may generate the precharge command PRE after a delay time corresponding to the weight 0.9*W passes from generating the write command WT.

Referring to the last timing diagram of FIG. 4, when the first code OP[3:5] indicates the data 110, the timing scheduler 210 may select the weight 0.5*W, and the function generator 450 may generate the precharge command PRE after a delay time corresponding to the weight 0.5*W passes from generating the write command WT. That is, the data 110 of the first code OP[3:5] indicates that the memory device 300 operates at a relatively higher temperature of the operation permission range for example, −30° C.≤temperature<90° C. Consequently, the write recovery time (tWR) characteristic of the memory device 300 may have the smallest value, and the controller 200 may generate the precharge command PRE after the delay time corresponding to the weight 0.5*W having the smallest value from generating the write command WT.

As described above, as the temperature of the memory device 300 increases from approximately −30° C. to 90° C., a weight applied by the timing scheduler 210 may be decreased from 1*W to 0.5*W. The rate at which the weight is decreased may be set on the basis of the rate at which the write recovery time (tWR) characteristic of the memory device 300 changes depending on temperature. The number of weights to be applied by the controller 200 and the change rate illustrated in FIG. 4 may be variously decided according to the rate at which the write recovery time (tWR) characteristic of the memory device 300 changes depending on temperature; however, the embodiment is not limited thereto.

In the present technology, operation timings of the memory device are not simultaneously controlled according to relatively bad conditions, for example, low temperature, but are flexibly controlled according to temperature. Consequently, it is possible to guarantee a stable operation of the memory device at a low temperature as well as performance improvement of the memory device at a high temperature.

Particularly, since the write recovery time (tWR) characteristic of the memory device changes depending on temperature, when a precharge operation is performed after a write operation, i.e., at an write to precharge operation, the time interval of the write and precharge commands are adjusted on the basis of the temperature of the memory device. Consequently, it is possible to substantially prevent a read error of the memory device from occurring at a low temperature while enabling high performance of the memory device at a high temperature.

Although various embodiments have been described for illustrative purposes, it will be apparent to those skilled in the art that various changes and modifications may be made without departing from the spirit and scope of the invention as defined in the following claims.

What is claimed is:

1. A memory system comprising:
a memory device configured to store input data with a first time interval that is adjusted in response to a write command and a precharge command; and
a controller configured to generate the write command and the precharge command, and to control the memory device,
wherein the controller sets a change rate of the first time interval according to a temperature of the memory device, and adjusts a time interval between the write command and the precharge command on a basis of the set change rate and the temperature of the memory device.

2. The memory system of claim 1, wherein the controller comprises:
a timing scheduler configured to adjust the time interval of the write command and the precharge command according to the set change rate in response to a digital code indicating the temperature of the memory device.

3. The memory system of claim 2, wherein the timing scheduler comprises:
a receiver configured to receive and transfer the digital code according to whether the digital code is updated;
a latch configured to store the digital code transferred from the receiver;
a decoder configured to decode the digital code stored in the latch and activate a corresponding signal of a plurality of selection signals; and
a control logic configured to apply a corresponding weight of a plurality of weights in response to the activated selection signal.

4. The memory system of claim 3, wherein the control logic comprises:
a plurality of registers configured to store the plurality of weights that are determined on the basis of the set change rate.

5. The memory system of claim 3, wherein the plurality of weights indicate a delay time between the write command and the precharge command.

6. The memory system of claim 3, wherein the timing scheduler further comprises:
a function generator configured to generate the write command and the precharge command on a basis of a delay time according to the applied weight.

7. The memory system of claim 2, wherein the memory device comprises:
a temperature code generator configured to monitor the temperature and generate the monitored temperature as the digital code.

8. The memory system of claim 7, wherein the memory device provides the controller with the digital code together with read data in response to a read command.

9. The memory system of claim 2, wherein the digital code comprises:
a first code indicating the temperature of the memory device; and
a second code indicating an offset and update information of the first code.

10. The memory system of claim 1, wherein the first time interval corresponds to a physical time taken for a memory cell included in the memory device to stably store the input data.

11. A memory system comprising:
a memory device configured to generate and output a digital code based on an internal temperature; and
a controller configured to generate write and precharge commands for a write operation of the memory device, and to control the memory device,
wherein the controller decreases a time interval between the write command and the precharge command on a basis of the digital code as the internal temperature of the memory device increases.

12. The memory system of claim 11, wherein the controller comprises:
a timing scheduler configured to adjust the time interval between the write command and the precharge command by using a selected weight on a basis of the digital code.

13. The memory system of claim 12, wherein the timing scheduler comprises:
a receiver configured to receive and transfer the digital code according to whether the digital code is updated;
a latch configured to store the digital code transferred from the receiver;
a decoder configured to decode the digital code stored in the latch and activate a corresponding signal of a plurality of selection signals; and
a control logic configured to apply a corresponding weight of a plurality of weights in response to the activated selection signal.

14. The memory system of claim 13, wherein, as the internal temperature of the memory device increases, the weight applied by the control logic decreases.

15. The memory system of claim 13, wherein the timing scheduler further comprises:
a function generator configured to generate the precharge command after a delay time from generating the write command, wherein the delay time is determined on a basis of the weight applied by the control logic.

16. The memory system of claim 11, wherein the memory device generates the digital code on a basis of a rate at which a time taken to store input data changes depending on the internal temperature of the memory device.

17. The memory system of claim 16, wherein the time taken for the memory device to store the input data corresponds to a physical time taken for a memory cell included in the memory device to stably store the input data.

18. The memory system of claim 11, wherein the memory device comprises:
a temperature code generator configured to monitor the internal temperature and generate the monitored internal temperature as the digital code.

19. The memory system of claim 11, wherein the memory device provides the controller with the digital code together with read data in response to a read command.

20. The memory system of claim 11, wherein the digital code comprises:
a first code indicating the internal temperature of the memory device; and
a second code indicating an offset and update information of the first code.
